(19) United States
(12) Patent Application Publication
(10) Pub. No.: US 2025/0336765 A1
(43) Pub. Date: Oct. 30, 2025

(54) ELECTRONIC PACKAGE ASSEMBLY WITH A COOLING SYSTEM AND A METHOD FOR FORMING THE SAME

(71) Applicant: STATS ChipPAC Pte. Ltd., Singapore (SG)

(72) Inventors: JiSeon LEE, Incheon (KR); BumRyul MAENG, Incheon (KR); HyunKyu LEE, Incheon (KR); MinGyu KIM, Incheon (KR)

(21) Appl. No.: 19/187,966

(22) Filed: Apr. 23, 2025

(30) Foreign Application Priority Data
Apr. 24, 2024 (CN) 202410496159.0

(51) Int. Cl. H01L 23/46; H01L 21/56; H01L 23/26; H01L 23/31; H01L 23/538; H01L 25/00; H01L 25/11

(52) U.S. Cl. CPC H01L 23/46; H01L 21/56; H01L 23/26; H01L 23/5386; H01L 25/112; H01L 25/50; H01L 23/3135; H01L 2225/1058; H01L 2225/1094

(57) ABSTRACT

An electronic package assembly and a method for forming the same are provided. The electronic package assembly comprises: a base package substrate, at least one base electronic component, and a base mold cap; a support frame attached on the base mold cap, wherein the support frame has a base opening exposing the base mold cap and the front surface of the base electronic component, and an upper opening in fluid communication with the base opening; an upper package substrate supported on the support frame, at least one upper electronic component facing towards the base electronic component, and an upper mold cap accommodated within the support frame, and the upper mold cap has a height smaller than that of the support frame to form a cooling passage between the upper mold cap and the base mold cap; and wherein the upper package substrate comprises an inlet and an outlet formed therethrough.

### TECHNICAL FIELD

The present application generally relates to semiconductor packaging technology, and more particularly, to an electronic package assembly with a cooling system and a method for forming the same.

### BACKGROUND OF THE INVENTION

In recent years, semiconductor industry is constantly faced with complex integration challenges as more and more electronic modules are packed into a single device for multi-functionalities. When the device is in operation, the multiple electronic modules incorporated in the device may generate heat, especially for those high-performance logic chips and memory chips such as central processing units (CPU), graphics processing units (GPU) and high bandwidth memories (HBM). Under such circumstances, the generated heat should be dissipated timely to guarantee good functionalities of the electronic modules. Typically, a heat spreader may be attached on those electronic modules to facilitate heat dissipation. However, it is noted that an efficiency of the existing heat dissipation methods may still be limited, especially for the device including high-performance chips and with a stacked structure.

Therefore, a need exists for an electronic package assembly with an improved heat dissipation capacity.

### SUMMARY OF THE INVENTION

An objective of the present application is to provide an electronic package assembly with an improved heat dissipation capacity.

According to an aspect of the present application, an electronic package assembly is provided. The electronic package assembly comprises: a base electronic package comprising: a base package substrate, at least one base electronic component mounted on the base package substrate, and a base mold cap formed on the base package substrate to encapsulate the at least one base electronic component but expose a front surface of the at least one base electronic component; a support frame attached on the base mold cap, wherein the support frame has a base opening exposing a portion of the base mold cap and the front surface of the at least one base electronic component, and an upper opening opposite to the base opening and in fluid communication with the base opening; an upper electronic package attached on the support frame and comprising: an upper package substrate supported on the support frame, at least one upper electronic component mounted on the upper package substrate and facing towards the at least one base electronic component, and an upper mold cap formed on the upper package substrate to encapsulate the at least one upper electronic component but expose a front surface of the at least one upper electronic component, wherein the upper mold cap is accommodated within the support frame through the upper opening of the support frame, and the upper mold cap has a height smaller than that of the support frame to form a cooling passage between the upper mold cap and the base mold cap, wherein the cooling passage is configured for accommodating a coolant fluid and being in direct contact with the exposed ones of the at least one base electronic component and the at least one upper electronic component; and wherein the upper package substrate comprises an inlet and an outlet formed therethrough and aligned with the upper opening to pump into and output from the cooling passage the coolant fluid, respectively.

According to another aspect of the present application, a method for forming an electronic package assembly is provided. The method comprises: mounting at least one base electronic component on a base package substrate; forming a base mold cap on the base package substrate to encapsulate the at least one base electronic component but expose a front surface of the at least one base electronic component; mounting at least one upper electronic component on an upper package substrate; forming an upper mold cap on the upper package substrate to encapsulate the at least one upper electronic component but expose a front surface of the at least one upper electronic component; attaching a support frame on the front surface of the base mold cap, wherein the support frame has a base opening exposing a portion of the base mold cap and the front surface of the at least one base electronic component, and an upper opening opposite to the base opening and in fluid communication with the base opening; attaching the upper package substrate on the support frame, wherein the upper mold cap is accommodated within the support frame through the upper opening of the support frame and facing towards the base mold cap, and the upper mold cap has a height smaller than that of the support frame to form a cooling passage between the upper mold cap and the base mold cap, wherein the cooling passage is configured for accommodating a coolant fluid and being in direct contact with the exposed ones of the at least one base electronic component and the at least one upper electronic component; and forming an inlet and an outlet through the upper package substrate.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A illustrates an electronic package assembly according to a first embodiment of the present application.

FIG. 1B illustrates a top view of a support frame shown in FIG. 1A.

FIGS. 2A to 2F illustrate various steps of a method for forming an electronic package assembly according to a second embodiment of the present application.

FIG. 3 illustrates an electronic package assembly according to a third embodiment of the present application.

FIGS. 4A to 4E illustrate various steps of a method for forming an electronic package assembly according to a fourth embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, for a device including multiple electronic modules packed therein, the electronic modules may generate significant heat when the device is in operation, especially for those high-performance logic chips and memory chips such as central processing units (CPUs), graphics processing units (GPUs) and high bandwidth memories (HBM s). Under such circumstances, the generated heat should be dissipated timely to guarantee good functionalities of the electronic modules.

To address the heat dissipation issue, a new electronic package assembly with a cooling system is provided. The electronic package assembly includes a base electronic package, an upper electronic package, and a support frame attached between the upper electronic package and the base electronic package. The support frame can form a cooling passage between the upper and base electronic package, which allows for a coolant fluid to flow therethrough and being in direct contact with the upper electronic package and the base electronic package. Due to the direct contact with the electronic packages, the coolant fluid can efficiently dissipate heat generated within the device. It can be appreciated that the electronic package assembly can be used in devices with a multi-layer structure and being stacked with high-performance electronic modules, which requires an improved heat dissipation capacity.

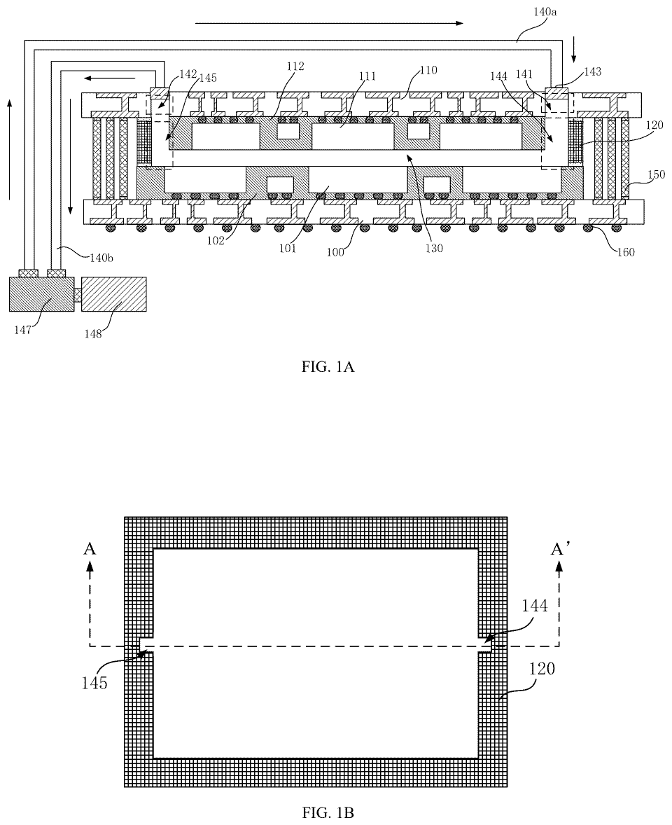

FIG. 1A illustrates an electronic package assembly according to a first embodiment of the present application.

As shown in FIG. 1A, the electronic package assembly has a two-layer stacked structure, i.e., a base electronic package at a lower layer and an upper electronic package at an upper layer. The base electronic package includes a base package substrate 100 with embedded interconnect wires. The base package substrate 100 has a front surface and a back surface, which are opposite to each other. The front surface of the base package substrate 100 may serve as a platform where electronic component(s) and conductive blocks can be mounted. In some embodiments, the electronic package assembly may be a double sided mounted (DSM) package, and accordingly, the back surface may also serve as another platform where electronic component(s) may be mounted. Multiple sets of conductive pads (not shown) can be formed on the front surface and/or the back surface of the base package substrate 100 for the mounting of the electronic components. It can be appreciated that the multiple sets of conductive pads may be exposed portions of interconnect wires formed within the base package substrate 100.

The base electronic package includes at least one base electronic component 101 mounted on the front surface of the base package substrate 100 via solder bumps. In some embodiments, the at least one base electronic component 101 may include conductive pads on its back surface for mounting the base electronic component 101 to the base package substrate 100. The base electronic component 101 may include a high-performance chip such as a central processing unit (CPU), a graphics processing unit (GPU) and a high bandwidth memory (HBM), which may have high power consumption and generate extensive heat when it is in operation. Furthermore, a base mold cap 102 is formed on the base package substrate 100 to encapsulate the at least one base electronic component 101. As shown in FIG. 1A, the base mold cap 102 encapsulates a lateral surface of the at least one base electronic component 101 but exposes a front surface of the at least one base electronic component 101. The front surface of the at least one base electronic component 101 refers to a surface of the base electronic component 101 away from the base package substrate 100 and the solder bumps. In some embodiments where more than one base electronic components 101 are mounted on the base package substrate 100, front surfaces of all of the base electronic components 101 may be substantially at the same horizontal plane. Furthermore, the base electronic package may include at least one additional base electronic component. The additional base electronic component may be passive electronic components such as a resistor or a capacitor, or other smaller electronic components. In some embodiments, the additional base electronic component may have a smaller height compared with that of the base electronic component 101. That is, the base mold cap 102 may encapsulate a lateral surface and a front surface of the at least one additional base electronic component.

As shown in FIG. 1A, similar as the base electronic package, the upper electronic package includes an upper package substrate 110, at least one upper electronic component 111 mounted on the upper package substrate 110 via solder bumps, and an upper mold cap 112 formed on the upper package substrate 110 to encapsulate the at least one upper electronic component 111 but expose a front surface of the at least one upper electronic component 111. The details of the upper electronic package may be similar to those illustrated with respect to the base electronic package, which will not be elaborated in detail here for simplicity.

Still referring to FIG. 1A, the electronic package assembly further includes a support frame 120 attached between the base electronic package and the upper electronic package. FIG. 1B is a top view of the support frame 120 shown in FIG. 1A, and a cross-sectional view of the support frame 120 is shown in FIG. 1A along line AA′ in FIG. 1B.

As shown in FIGS. 1A and 1B, the support frame 120 is attached on a front surface of the base mold cap 102, which supports and locates the upper electronic package. In some embodiments, the support frame 120 may include a liquid crystal polymer or a stainless steel, or other similar materials that has a sufficient strength. In some embodiments, the support frame 120 has a rectangular annulus layout including four long boards connected with one another, and is attached on a marginal region of the base mold cap 102. In some other embodiments, the support frame 120 may have a different layout, such as a ring, a hexagon annulus or an octagon annulus, as long as the support frame can be attached on the base mold cap and accommodate the upper electronic package. In a preferred embodiment, the layout of the support frame may mate with a layout of the base mold cap and a layout of the upper mold cap. Still referring to FIG. 1A, the support frame 120 has a base opening and an upper opening opposite to the base opening. The upper opening is in fluid communication with the base opening, forming a vertical channel between a front surface and a back surface of the support frame 120. In particular, the base opening exposes at least a portion of the front surface of the base mold cap 102 and the front surface of the at least one base electronic component 101.

The upper electronic package may be flipped over and then mounted on the support frame 120, and therefore the upper electronic component 111 may face towards the base electronic package. In particular, the front surface of the upper package substrate 110 may be supported on the support frame 120 at a marginal region of the upper package substrate 110. The symmetric layout of the support frame 120 may provide a balanced supporting force to the upper package substrate 110. Furthermore, the upper mold cap 112 and the upper electronic component 111 may be accommodated within the vertical channel of the support frame 120 through the upper opening of the support frame 120. The front surface of the upper mold cap 112 and the at least one upper electronic component 111 may face towards the front surface of the base mold cap 102 and the at least one base electronic component 101. Moreover, the upper mold cap 112 has a height smaller than that of the support frame 120. Since both of the support frame 120 and the upper mold cap 112 are attached on the same front surface of the upper package substrate 110, a height difference of the support frame 120 and the upper mold cap 112 forms a cooling passage 130 between the upper mold cap 112 and the base mold cap 102, which may be used for accommodating a coolant fluid to flow therein and take away heat generated by the base electronic component(s) 101 and the upper electronic component(s) 111. In additional, the upper mold cap 112 has a size smaller than that of the base mold cap 102, which enables the cooling passage 130 to extend upwards to the upper package substrate 110. The upper package substrate 110 further includes an inlet 141 and an outlet 142 formed through the upper package substrate 110 and aligned with the upper opening of the support frame 120. As shown in FIG. 1B, the support frame 120 also includes a pair of slots 144, 145 disposed opposite to each other and at an inner wall of the support frame 120. The pair of slots 144, 145 may be formed through the support frame 120, which extend vertically between the front surface and the back surface of the support frame 120. The slots 144, 145 are vertically aligned with the inlet 141 and the outlet 142, respectively, to allow the coolant fluid to flow into and out of the cooling passage 130. In some other embodiments, the pair of slots 144, 145 may also be formed within a middle region of the respective long boards of the support frame 120 and may be close to the electronic components.

Furthermore, the coolant fluid in the cooling passage 130 may be circulated and cooled down through a pump 147 and a radiator 148 connected to the pump 147. In the embodiment shown in FIG. 1A, two pipes 140a, 140b may be connected to the cooling passage 130, with one of the pipes 140a as an inlet pipe for bringing the coolant fluid into the cooling passage 130 and the other pipe 140b as an outlet pipe for bringing the coolant fluid out of the cooling passage 130. The pipes 140a, 140b may include a material such as polyvinyl chloride (PVC), polyurethane (PU), metal, etc. In particular, the cooling passage 130 may be connected to one end of each of the two pipes 140a, 140b through the inlet 141 and outlet 142, respectively. The other end of each of the two pipes 140a, 140b may be connected to a pump 147, which pumps the coolant fluid into one of the pipes 140a and out of the other pipe 140b, thereby circulating the coolant fluid within the pipes 140a, 140b and the cooling passage 130. A radiator 148 may be connected to the pump 147 to cool the coolant fluid when it comes into the pump 147. In some other embodiments, the radiator 148 may be coupled in one of the pipes 140a, 140b to dissipate heat from the coolant fluid flowing therein.

When a device incorporating the electronic package assembly with such a cooling system is in operation, heat may be generated by the base electronic component(s) 101 and the upper electronic component(s) 111. The generated heat may gradually cumulate within the base mold cap 102 and the upper mold cap 112. The pump 147 may be turned on to pump the coolant fluid into the pipe 140a, and the coolant fluid may then flow through the pipe 140a and the inlet 141 into the cooling passage 130, which takes away heat generated within the electronic package assembly after direct heat exchange between the coolant fluid and the electronic components there. Then the heated coolant fluid may flow out of the cooling passage 130 through the outlet 142 into the pipe 140b, returning to the pump 147, thereby circulation of the coolant fluid is completed. Additionally, the radiator 148 may also be turned on to cool the coolant fluid down to a lower temperature, which is applicable for a new cooling circulation. It can be appreciated that the radiator 148 may be an active radiator or a passive radiator. Furthermore, the electronic package assembly may include valves 143 each disposed at the inlet 141 and the outlet 142 within the respective pipes 140a, 140b to regulate a flow rate of the coolant fluid within the cooling passage 130. When the device is operating with a high power, i.e., more heat may be generated during the operation of the device, the valves 143 may be regulated to accelerate the flow rate of the coolant fluid.

As shown in FIG. 1A, the base mold cap 102 and the upper mold cap 112 fully encapsulate main bodies of the base electronic component(s) 101 and upper electronic component(s) 111 and only expose the front surfaces of the electronic components 101, 111. To be more specific, the base mold cap 102 and the upper mold cap 112 may encapsulate lateral surfaces of the electronic components 101, 111, bottom surfaces of the electronic components 101, 111 and electrical connections between the package substrates 100, 110 and respective electronic components 101, 111 such as conductive pads and solder bumps. In addition, electrically conductive units within the electronic components 101, 111 may also be fully encapsulated during a preformed process, for example, which leaves the front surfaces of the electronic components 101, 111 as sealed surfaces (e.g., silicon oxide surfaces, non-doped silicon surfaces, or other similar non-conductive surfaces) without any exposure of the electrically conductive units at the front surfaces. As such, potential electrical leakage or short-circuit failure can be prevented even though the coolant fluid may be in direct contact with the front surfaces of the mold caps 102, 112 and the electronic components 101, 111, thereby enabling good electrical reliability and safety of the electronic package assembly. Moreover, in some embodiments, the coolant fluid includes a deionized coolant fluid (e.g., deionized water), which is electrically insulated from the base electronic component(s) 101 and the upper electronic component(s) 111 when the coolant fluid is flowing through the cooling passage 130, allowing for improved reliability of the electronic package assembly.

The electronic package assembly with such a cooling system may have following advantages. Firstly, since the upper electronic package, the cooling passage and the base electronic package form a sandwich-like structure with the cooling passage formed therein, the coolant fluid in the cooling passage may be in direct contact with the exposed front surfaces of the at least one base electronic component, the base mold cap, the at least one upper electronic component and the upper mold cap simultaneously, which may dissipate heat in a more efficient way. Secondly, the cooling passage within the electronic package assembly is defined by the respective surfaces of the upper mold cap, the base mold cap and the support frame, which forms a compact package structure without the need of an extra space for a cooling tube or heat spreader. Thirdly, no additional processes, e.g., etching or trenching, is needed to form the cooling passage within the electronic package assembly, which saves a production cost of the device. In some embodiments, once the coolant fluid enters into the cooling passage, it may spread across almost the front surfaces of the base mold cap and the upper mold cap, thereby creating a relatively large cooling interface and allowing for more sufficient cooling of the electronic package assembly.

As shown in FIGS. 1A and 1B, one pair of the inlet 141 and the outlet 142 within the upper package substrate 110 extend vertically through the support frame 120 and are connected with the cooling passage 130 via the pair of slots 144, 145. In some other embodiments, more than one pair of the inlet 141 and the outlet 142 and more than one pair of the slots 144, 145 are formed within the upper package substrate 110 and the support frame 120, respectively. To be more specific, multiple pairs of slots may be arranged around the support frame 120, for example, at the four long boards of the rectangular annulus in the embodiment shown in FIG. 1B. Accordingly, more inlets and outlets may be formed through the upper package substrate which are vertically aligned with respective slots of the support frame 120. In addition, more pipes or branches of pipes may be provided and connected to those inlets and outlets. As such, the coolant fluid may enter into the cooling passage 130 with a more uniform distribution and the coolant fluid may flow across a larger area of the mold caps 102, 112 and electronic components 101, 111, which allows for homogeneous cooling of the electronic package assembly.

In some other embodiments, a support grid may be formed within the cooling passage 130 to support the upper electronic package on the base electronic package, along with the support frame. In some embodiments, the support grid is connected with the support frame 120 as a single piece. To be more specific, the support grid may be a plurality of parallel vertical pillars attached between the base mold cap 102 and the upper mold cap 112. The vertical pillars may be separated from each other to guarantee the flow of the coolant fluid within the cooling passage 130, while the vertical pillars may also be connected to the support frame 120 with horizontal linkages to form a single piece, for example. Both of the vertical pillars and the horizontal linkages may expose a significant portion of the front surface(s) of the upper electronic component(s) 111 and the base electronic component(s) 101 to allow for heat exchange between the electronic components with the coolant fluid. In some alternative embodiments, the base mold cap 102 may include protruding molding blocks on its front surface, which may be formed in a same molding process together with the base mold cap 102. The protruding molding blocks may provide mechanical support to the upper mold cap 112 after the upper electronic package is attached on the support frame 120. In particular, the protruding molding blocks may not cover the front surface of the base electronic component(s) 101 but may cover a front surface of additional base electronic component(s) 101 which may generate less heat compared with the base electronic component(s) 101. It can be appreciated that the protruding molding blocks may also or alternatively be formed on the front surface of the upper mold cap 112.

In the embodiment shown in FIGS. 1A and 1B, the inlet 141 and the outlet 142 are arranged around the upper mold cap 112. In some other embodiments, at least one additional inlet or additional outlet may be formed through the upper mold cap 112 and the upper package substrate 110, which may be arranged in a central region of the upper mold cap 112 and the upper package substrate 110. As such, the coolant fluid may also pass through an interior of the upper mold cap 112, which increases a cooling surface of the upper electronic component(s) 111 and the upper mold cap 112.

Furthermore, as shown in FIG. 1A, the electronic package assembly may further include at least one conductive component 150 formed between the base package substrate 100 and the upper package substrate 110. In this embodiment, the at least one conductive component 150 may be disposed around the support frame 120. To be more specific, at least a portion of the base package substrate 100, for example, a marginal region around the base mold cap 102 may be exposed for mounting of external electronic modules. Similarly, at least a portion of the upper package substrate 110 may also be exposed for mounting the support frame 120 and external electronic modules. The least one conductive component 150 may be attached between the exposed portion of the base package substrate 100 and the exposed portion of the upper package substrate 110, thereby forming electrical connection between the base package substrate 100 and the upper package substrate 110. In this way, the upper electronic package and the base electronic package may be interconnected to form an integral circuit system. In some embodiments, the conductive components may include a conductive pillar, an e-bar block or a bonding wire. Additionally, a plurality of additional solder bumps 160 may be formed on the back surface of the base package substrate 100 for mounting the electronic package assembly onto external electronic modules.

It can be appreciated that, although FIG. 1A depicts a two-layer structure with an upper electronic package stacked on a lower base electronic package, the number of electronic packages stacked together may not be limited to two, and more than two layers of packages may be integrated together in some examples. Accordingly, additional support frame(s) may also be introduced to form additional cooling passage(s) between the stacked electronic packages at adjacent layers.

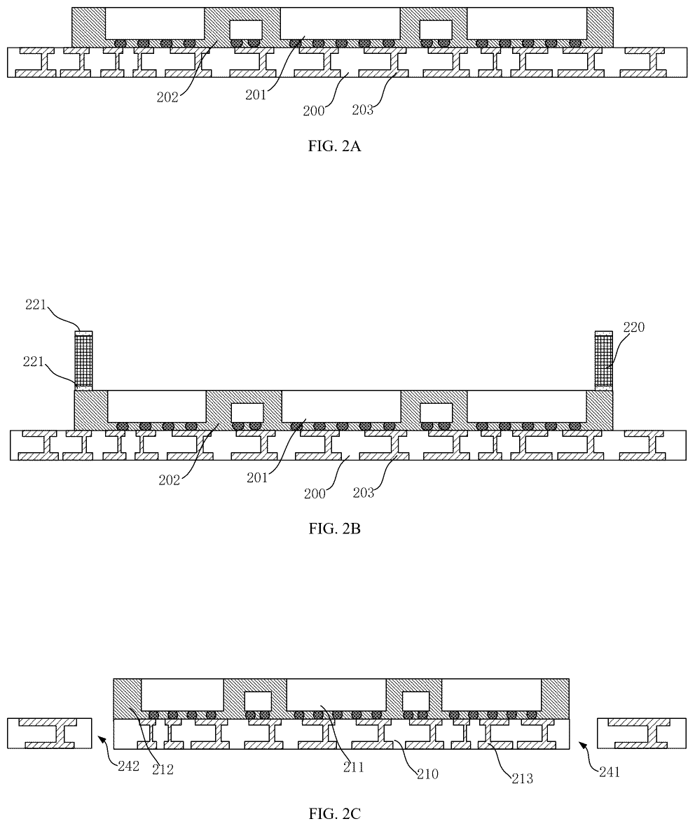

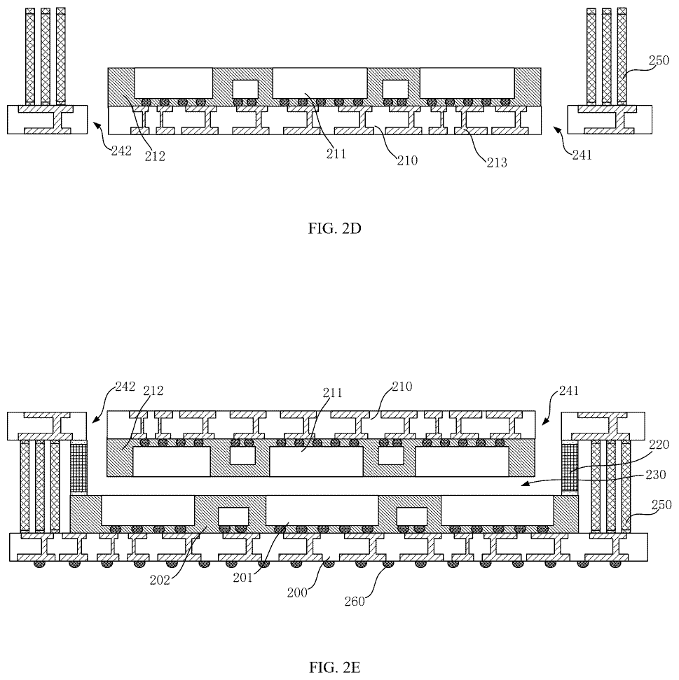

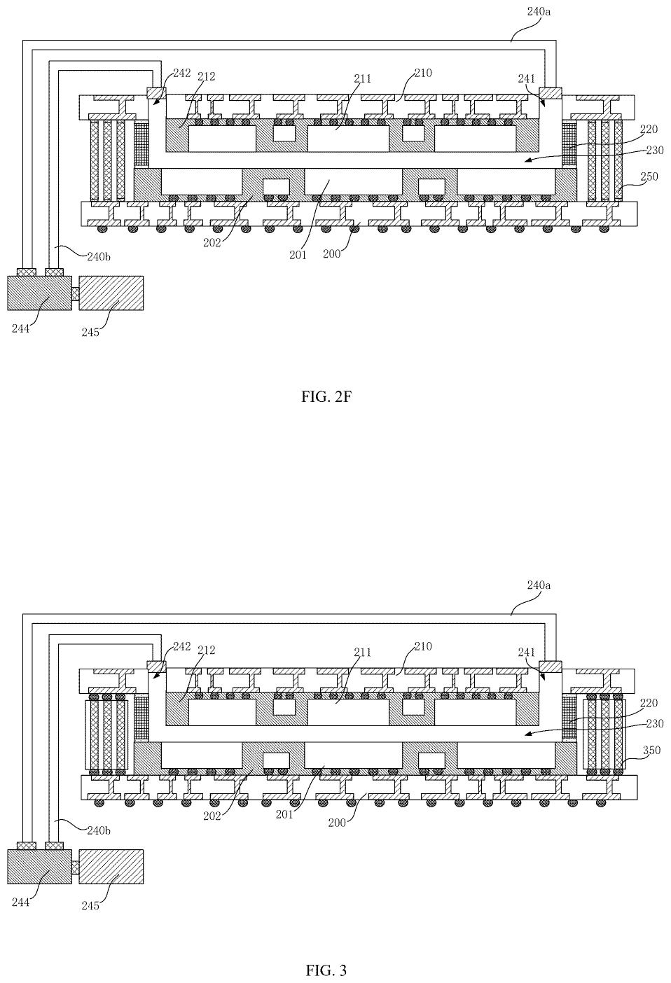

FIGS. 2A to 2F illustrate various steps of a method for forming an electronic package assembly according to a second embodiment of the present application. The electronic package assembly may be similar to the electronic package assembly illustrated in FIGS. 1A and 1B.

As shown in FIG. 2A, a base package substrate 200 is provided with embedded interconnect wires 203. At least one base electronic component 201 is mounted on a front surface of the base package substrate 200 via solder bumps. Next, a base molding material is formed on the base package substrate 200 to encapsulate the at least one base electronic component 201. The base molding material is formed using a molding process such as an injection molding process, which covers respective front surfaces of the base electronic component(s) 201 for encapsulation. The base molding material includes epoxy, polyester resin, etc. In some embodiments, the base molding material may be formed using various other molding technologies, including a transfer molding process, a compression molding process or a film-assisted molding (FAM) process. In some embodiments, the base molding material is selectively formed on a central region of the base package substrate 200, while a marginal region of the base package substrate 200 is exposed for mounting external electronic components. Next, a grinding process may be implemented on a front surface of the base molding material to expose a front surface of the at least one base electronic component 201, thereby forming a base mold cap 202 with its front surface aligned with the front surface of the base electronic component(s) 201. In this way, a base electronic package may be formed.

Next, as shown in FIG. 2B, a support frame 220 is attached on the front surface of the base mold cap 202. The support frame 220 has a base opening exposing a portion of the base mold cap 202 and the front surface of the at least one base electronic component 201. The support frame 220 further includes an upper opening opposite to the base opening and in fluid communication with the base opening. The fluidly interconnected base opening and upper opening together form a channel that extend vertically through the support frame 220. In some embodiments, the support frame 220 further includes an adhesive material 221 dispensed on both of its back surface and front surface, which allows for firm attachment of the support frame 220 between the base mold cap 202 and an upper electronic package that may be attached later. In some embodiments, the support frame 220 also includes a pair of slots disposed opposite to each other at an inner wall of the support frame 220, which are formed passing through the support frame 220.

Next, as shown in FIG. 2C, an upper package substrate 210 is provided with embedded interconnect wires 213. At least one upper electronic component 211 is formed on a central region of the upper package substrate 210. Next, a pair of slots 241, 242 are formed through the upper package substrate 210 and around the at least one upper electronic component 211 while a majority of the upper package substrate 210 is still interconnected as a single piece. The pair of slots 241, 242 are used as an inlet 241 and an outlet 242 of a cooling passage that may be subsequently formed. It can be appreciated that the positions and layouts of the pair of slots 241, 242 may mate with those of the slots within the support frame 220.

Next, an upper mold cap 212 is formed on a central region of the upper package substrate 210 to encapsulate the at least one upper electronic component 211 but expose the slots 241, 242 and a marginal region of the upper package substrate 210. The upper mold cap 212 further exposes a front surface of the at least one upper electronic component 211. To be more specific, the formation of the upper mold cap 212 includes forming an upper molding material on the upper package substrate 210 to encapsulate the at least one upper electronic component 211, and then grinding a top portion of the upper molding material till the exposure of a front surface of the at least one upper electronic component 211, so as to form the upper mold cap 212. The formation of the upper mold cap 212 may be similar to the formation process of the base mold cap 202. In this way, an upper electronic package is formed.

In some other embodiments, the upper electronic package may be formed before the formation of the base electronic package. It can also be appreciated that the upper electronic package and the base electronic package may be formed simultaneously.

Next, as shown in FIG. 2D, at least one conductive component 250 is formed on the exposed front surface of the upper package substrate 210. The conductive component may include at least one conductive pillar with conductive pads formed on its front surface and back surface. The conductive pillars may include a metal material such as Cu or Al.

Next, as shown in FIG. 2E, the upper electronic package may be flipped over, and then the upper package substrate 210 may be attached on the support frame 220, where a marginal region of the front surface of the upper package substrate 210 may be attached on the support frame 220. The upper mold cap 212 is accommodated within the support frame 220 through the upper opening of the support frame 220 and faces towards the base mold cap 202. The upper mold cap 212 has a height smaller than that of the support frame 220, thereby forming a cooling passage 230 between the upper mold cap 212 and the base mold cap 202 after the attachment of the upper electronic package onto the support frame 220. During the attaching process, the pair of slots formed within the support frame 220 and the pair of slots (i.e., inlet 241 and outlet 242) formed within the upper package substrate 210 may be vertically aligned with each other, respectively, which are connected to the cooling passage 230 for fluid communication with external pipes. In some embodiments, a solder paste and/or a flux material may be dipped onto a front surface of the conductive pillar(s) 250 before attaching the upper package substrate 210 on the support frame 220. In this way, during the attaching step, the conductive pillar(s) 250 may also be mounted on the front surface of the base package substrate 200 to electrically connect the upper package substrate 210 with the base package substrate 200. Next, additional solder bumps 260 may be formed on a back surface of the base package substrate 200.

Next, as shown in FIG. 2F, pipes 240a, 240b may be fluidly connected with the cooling passage 230 via the inlet 241 and the outlet 242. A pump 244 may be connected to the pipes 240a, 240b to circulate the coolant fluid (which may be filled in later) within the pipes 240a, 240b and the cooling passage 230, and a radiator 245 may also be connected to the pump 244 to cool the coolant fluid, thereby forming the cooling system within the electronic package assembly.

More details of the above-mentioned components may be similar to those of the electronic package assembly illustrated in FIGS. 1A and 1B, which will not be elaborated in detail here for simplicity.

FIG. 3 illustrates an electronic package assembly according to a third embodiment of the present application. The electronic package assembly has a structure and a forming process similar as the electronic package assembly shown in FIGS. 2A to 2F, except that the conductive component 350 included in the electronic package assembly in FIG. 3 is an e-bar block 350 instead of the conductive pillar(s) 250 shown in FIG. 2F. To be more specific, the e-bar block 350 may include built-in conductive columns such as copper columns and an insulative base material separating the conductive columns from each other. In some embodiments, two e-bar blocks 350 may be mounted between an upper package substrate 210 and a base package substrate 200 via solder bumps, for example, at two lateral sides of the support frame 220.

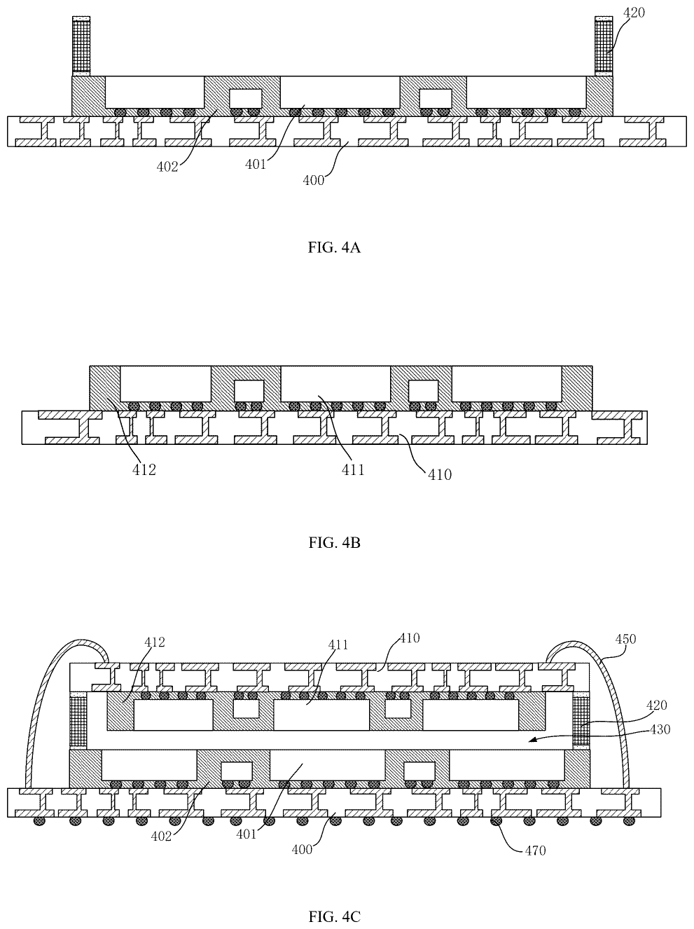

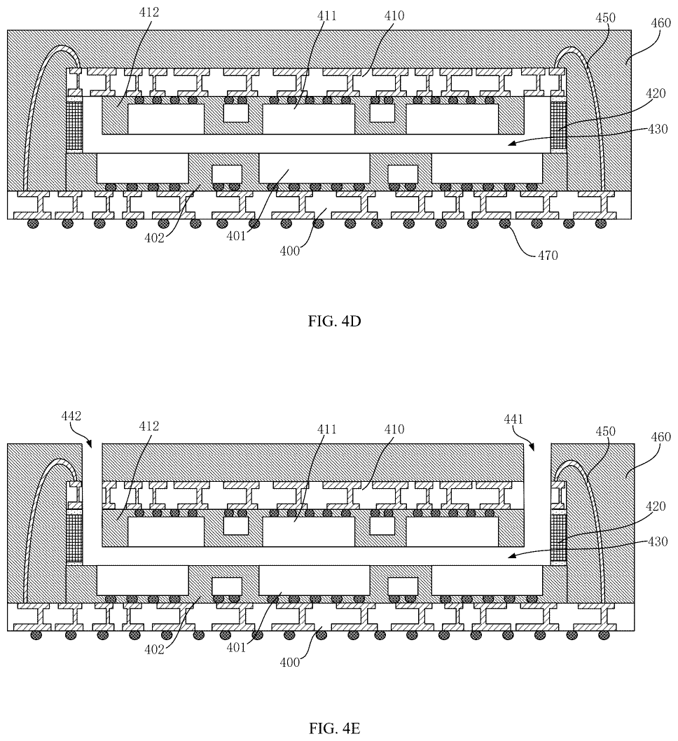

FIGS. 4A to 4E illustrate various steps of a method for forming an electronic package assembly according to a fourth embodiment of the present application.

As shown in FIG. 4A, a base package substrate 400 is provided with embedded interconnect wires. At least one base electronic component 401 is mounted on a front surface of the base package substrate 400 via solder bumps. Next, a base mold cap 402 is formed on the base package substrate 400 to encapsulate the at least one base electronic component 401 but expose a front surface of the at least one base electronic component 401, thereby forming the base electronic package. Next, a support frame 420 is attached on a front surface of the base mold cap 402.

As shown in FIG. 4B, an upper package substrate 410 is provided with embedded interconnect wires. At least one upper electronic component 411 is mounted on a central region of the upper package substrate 410. Next, an upper mold cap 412 is formed on a central region of the upper package substrate 410 to encapsulate the at least one upper electronic component 411 but expose a front surface of the at least one upper electronic component 411, thereby forming the upper electronic package.

Next, as shown in FIG. 4C, the upper electronic package may be flipped over and the upper package substrate 410 may be attached on the support frame 420. The upper mold cap 412 is accommodated within the support frame 420 through the upper opening of the support frame and faces towards the base mold cap 402. The upper mold cap 412 has a height smaller than that of the support frame 420, thereby forming a cooling passage 430 between the upper mold cap 412 and the base mold cap 402 after the attachment of the upper electronic package onto the support frame 420. Next, at least one bonding wire 450 is formed between the upper package substrate 410 and the base package substrate 400 to electrically connect the upper package substrate 410 with the base package substrate 400. In some embodiments, four or more bonding wires 450 may be formed on four corners of the base package substrate 400 and four respective corners of the upper package substrate 410. Each bonding wire 450 may include a flexible conductive material such as Cu or Al, which may or may not be coated with a polymer layer. The bonding wire 450 may provide an improved flexibility for layout designs of electrical connections between the upper electronic package and the base electronic package. Next, additional solder bumps 470 may be formed on a back surface of the base package substrate 400.

Next, as shown in FIG. 4D, an additional molding layer 460 is formed on the base package substrate 400 to encapsulate the base electronic package, the support frame 420, the upper electronic package and the at least one bonding wire 450. To be more specific, a back surface of the upper package substrate 410 is also encapsulated by the additional molding layer 460. Since the cooling passage 430 is sealed within the base package and the upper package, no molding material may flow into the cooling passage 430 through any opening.

Next, as shown in FIG. 4E, a portion of the upper package substrate 410 around the upper mold cap 412 and a portion of the additional molding layer 460 on the upper package substrate 410 may be removed to form an inlet 441 and an outlet 442, which are fluidly connected to the cooling passage 430 and have it fluidly connected with the external space. The inlet 441 and the outlet 442 may be formed through an etching process or a trenching process, with controlled stop when the cooling passage 430 is exposed. In this way, the cooling passage 430 may further be connected with external pipes via the inlet 441 and the outlet 442 to form a circulated cooling system within the electronic package assembly in subsequent steps. Furthermore, dusts or residuals left from the formation process of the inlet 441 and the outlet 442 may be removed by a coolant fluid flowing through the cooling passage 430.

While the exemplary electronic package assembly and method for forming an electronic package assembly of the present application is described in conjunction with corresponding figures, it will be understood by those skilled in the art that modifications and adaptations to the electronic package assembly and the forming method may be made without departing from the scope of the present invention.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. An electronic package assembly, comprising:
a base electronic package comprising: a base package substrate, at least one base electronic component mounted on the base package substrate, and a base mold cap formed on the base package substrate to encapsulate the at least one base electronic component but expose a front surface of the at least one base electronic component;
a support frame attached on the base mold cap, wherein the support frame has a base opening exposing a portion of the base mold cap and the front surface of the at least one base electronic component, and an upper opening opposite to the base opening and in fluid communication with the base opening;
an upper electronic package attached on the support frame and comprising: an upper package substrate supported on the support frame, at least one upper electronic component mounted on the upper package substrate and facing towards the at least one base electronic component, and an upper mold cap formed on the upper package substrate to encapsulate the at least one upper electronic component but expose a front surface of the at least one upper electronic component, wherein the upper mold cap is accommodated within the support frame through the upper opening of the support frame, and the upper mold cap has a height smaller than that of the support frame to form a cooling passage between the upper mold cap and the base mold cap, wherein the cooling passage is configured for accommodating a coolant fluid and being in direct contact with the exposed ones of the at least one base electronic component and the at least one upper electronic component; and
wherein the upper package substrate comprises an inlet and an outlet formed therethrough and aligned with the upper opening to pump into and output from the cooling passage the coolant fluid, respectively.

2. The electronic package assembly of claim 1, further comprising:
a pipe fluidly connected with the cooling passage via the inlet and the outlet;
a pump connected to the pipe to circulate the coolant fluid within the pipe and the cooling passage; and
a radiator connected to the pump to cool the coolant fluid.

3. The electronic package assembly of claim 2, further comprising one or more valves disposed within the pipe to regulate a flow rate of the coolant fluid within the cooling passage.

4. The electronic package assembly of claim 1, further comprising: at least one conductive component formed between the base package substrate and the upper package substrate for electrically connecting the base package substrate with the upper package substrate, wherein the at least one conductive component is disposed around the support frame.

5. The electronic package assembly of claim 4, wherein the conductive component comprises a conductive pillar.

6. The electronic package assembly of claim 4, wherein the conductive component comprises a bonding wire.

7. The electronic package assembly of claim 4, wherein the conductive component comprises an e-bar block.

8. The electronic package assembly of claim 1, wherein the base electronic component comprises a CPU, a GPU or a memory chip.

9. The electronic package assembly of claim 1, wherein the coolant fluid comprises a deionized coolant fluid.

10. The electronic package assembly of claim 1, wherein the support frame further comprises an adhesive material dispensed between the support frame and the base mold cap or between the support frame and the upper package substrate.

11. The electronic package assembly of claim 1, further comprising a support grid formed within the cooling passage and connected with the support frame as a single piece, wherein the support grid is configured to support the upper electronic package on the base electronic package but not to block the flow of the coolant fluid within the cooling passage.

12. A method for forming an electronic package assembly, the method comprising:
mounting at least one base electronic component on a base package substrate;
forming a base mold cap on the base package substrate to encapsulate the at least one base electronic component but expose a front surface of the at least one base electronic component;
mounting at least one upper electronic component on an upper package substrate;
forming an upper mold cap on the upper package substrate to encapsulate the at least one upper electronic component but expose a front surface of the at least one upper electronic component;
attaching a support frame on the front surface of the base mold cap, wherein the support frame has a base opening exposing a portion of the base mold cap and the front surface of the at least one base electronic component, and an upper opening opposite to the base opening and in fluid communication with the base opening;
attaching the upper package substrate on the support frame, wherein the upper mold cap is accommodated within the support frame through the upper opening of the support frame and facing towards the base mold cap, and the upper mold cap has a height smaller than that of the support frame to form a cooling passage between the upper mold cap and the base mold cap, wherein the cooling passage is configured for accommodating a coolant fluid and being in direct contact with the exposed ones of the at least one base electronic component and the at least one upper electronic component; and
forming an inlet and an outlet through the upper package substrate.

13. The method of claim 12, before attaching the upper package substrate on the support frame, the method further comprising:
forming at least one conductive component on the upper package substrate, wherein the at least one conductive component and the upper mold cap are on a same side of the upper package substrate; and
attaching the upper package substrate on the support frame further comprising: mounting the at least one conductive component on the base package substrate to electrically connect the upper package substrate with the base package substrate.

14. The method of claim 13, wherein the conductive component comprises a conductive pillar or an e-bar block.

15. The method of claim 13, wherein the inlet and the outlet are formed through the upper package substrate before attaching the upper package substrate on the support frame.

16. The method of claim 12, wherein after attaching the upper package substrate on the support frame, the method further comprises:
forming at least one bonding wire between the upper package substrate and the base package substrate to electrically connect the upper package substrate with the base package substrate; and
forming an additional molding layer on the base package substrate to encapsulate the base package substrate, the base mold cap, the support frame, the upper package substrate and the at least one bonding wire.

17. The method of claim 16, wherein the inlet and the outlet are formed through the upper package substrate and partially through the additional molding layer after forming an additional molding layer on the base package substrate.

18. The method of claim 12, wherein forming a base mold cap comprises:
forming a base molding material on the base package substrate to encapsulate the at least one base electronic component; and
grinding a front surface of the base molding material to expose a front surface of the at least one base electronic component to form the base mold cap; and wherein forming an upper mold cap comprises:
forming an upper molding material on the upper package substrate to encapsulate the at least one upper electronic component; and
grinding a front surface of the upper molding material to expose a front surface of the at least one upper electronic component to form the upper mold cap.
